(19) United States
(12) Patent Application Publication
(10) Pub. No.: US 2022/0271370 A1
(43) Pub. Date: Aug. 25, 2022

(54) Intelligent thermoelectric-battery integrated structure

(71) Applicant: University of Electronic Science and Technology of China, Chengdu (CN)

(72) Inventors: Chao Wang, Chengdu (CN); Jing Jiang, Chengdu (CN); Yi Niu, Chengdu (CN); Xinrui He, Chengdu (CN); Zhipeng Li, Chengdu (CN); Fu Li, Chengdu (CN); Pei Huang, Chengdu (CN); Yuehai Zhang, Chengdu (CN); Shan Gao, Chengdu (CN)

(21) Appl. No.: 17/741,342

(22) Filed: May 10, 2022

(51) Int. Cl. H01M 10/6572; H01L 35/32; H01M 10/42

(52) U.S. Cl. CPC H01M 10/6572; H01L 35/32; H01M 10/4257

(57) ABSTRACT

An intelligent thermoelectric-battery integrated structure, which belongs to the field of new energy device, is provided. The structure intelligently controls the temperature of the single cells inside the battery pack by means of direct contact, so as to reduce the temperature and cut off the occurrence of thermal runaway from the root cause. In addition, the Seebeck voltage generated based on the temperature difference can directly store energy inside the battery when charging, and can increase the overall output voltage when discharging. The advantage of this structure solves the contradiction between the difficulty of achieving high energy density and high safety performance for traditional batteries at the same time, and provides a practical solution for the development and utilization of a new generation of high-performance batteries.

### BACKGROUND OF THE PRESENT INVENTION

### Field of Invention

The invention relates to the field of new energy devices, and more particularly to an intelligent thermoelectric-battery integrated structure which combines thermoelectricity and battery and is based on the Seebeck effect of thermoelectric conversion and the Peltier effect of electric-thermal conversion.

### Description of Related Arts

Batteries are an indispensable mobile energy source in human production and life, and have penetrated into various industries including transportation, communication, and biomedicine. However, with the rapid change of electronic equipment, people's demand for batteries with high energy density and high power density is becoming more and more urgent, followed by the huge safety hazard brought by the thermal runaway of the battery. There are two main ways of battery thermal runaway: internal path and external path. The internal path refers to thermal runaway caused by chemical reactions inside the battery, and the external path refers to thermal runaway caused by smoke, fire or explosion outside the battery, both of which will seriously endanger the life and property safety of users. Therefore, how to effectively control thermal runaway is the key to improve battery safety performance. Compared with the thermal runaway generated by the external path, the thermal runaway of the internal path is mainly for the battery itself, which is particularly important. At present, there are two main ways to manage thermal runaway inside the battery, air cooling and liquid cooling. However, in these two cooling methods, the battery pack and the condenser are two independent components, which leads to the separate processing of the battery pack and the cooling system, so that the full potential of the cooling system cannot be fully utilized. In addition, as far as the battery pack is concerned, there will also be uneven cooling between the internal single cells, which makes it impossible to uniformly adjust the temperature, which increases safety hazards. Therefore, it may be a way to overcome this limitation if the cooling material can be brought into direct contact with the single cells. Based on this, we propose a new structure for smart thermoelectric battery integration that embeds thermoelectric materials directly inside the battery. Compared with the traditional air-cooled and liquid-cooled cooling methods, this structure can intelligently control the temperature of the single cells inside the battery pack through strict thermal control from the perspective of single cells, thereby cutting off thermal runaway at the root cause. In addition, the Seebeck voltage generated based on the temperature difference can be directly stored inside the battery when the battery is charged, and the overall output voltage can be increased when the battery is discharged. This structure provides an implementation solution for batteries with both high safety and high energy density, which is expected to guide the development and application of a new generation of high-performance batteries.

### SUMMARY OF THE PRESENT INVENTION

The main purpose of the technology of the present invention is to develop an intelligent thermoelectric-battery integrated structure based on the Seebeck effect of the thermo-electric conversion and the Peltier effect of the electric-thermal conversion. The structure intelligently controls the temperature of the single cells inside the battery pack by means of direct contact, so as to reduce the temperature and cut off the occurrence of thermal runaway from the root cause. In addition, the Seebeck voltage generated based on the temperature difference can store energy directly inside the battery when the battery is charging, and can increase the overall output voltage when it is discharging. The advantages of this structure solve the contradiction between the difficulty of achieving high energy density and high safety performance for traditional batteries at the same time, and provide a practical solution for the development and utilization of a new generation of high-performance batteries.

In order to achieve the above object, the technical scheme adopted in the present invention is as follows:

An intelligent thermoelectric-battery integrated structure is characterized in that the structure comprises: a left PN type semiconductor, a battery, and a right PN type semiconductor; the left PN type semiconductor is connected to the positive electrode of the battery through a left insulating non-thermal insulation layer, and the right PN type semiconductor Connect to the negative electrode of the battery through the right insulating non-thermal insulating layer;

The left PN-type semiconductor comprises: a left PN-type conductive layer, a left P-type doping region, a left N-type doping region, a left P-type conductive layer, a left N-type conductive layer; a left P-type doping region and a left N-type doping region One end of the doped region is connected to the left PN-type conductive layer, and the rest is kept electrically isolated; the other end of the left P-type doped region is connected to the left P-type conductive layer, and the other end of the left N-type doped region is connected to the left N-type conductive layer Layer connection; the left PN type conductive layer is connected to the positive electrode of the battery through the left insulating non-thermal insulation layer;

The right PN-type semiconductor comprises: a right PN-type conductive layer, a right P-type doped region, a right N-type doped region, a right P-type conductive layer, a right N-type conductive layer; a right P-type doped region and a right N-type doped region One end of the doped region is connected to the right PN-type conductive layer, and the rest is kept electrically isolated; the other end of the right P-type doped region is connected to the right P-type conductive layer, and the other end of the right N-type doped region is connected to the right N-type conductive layer Layer connection; the right P-type conductive layer and the right N-type conductive layer are connected to the negative electrode of the battery through the right insulating non-thermal insulating layer.

Further, the battery comprises a positive electrode, an electrolyte, and a negative electrode, the electrolyte is provided with a separator, and the positive electrode, the electrolyte, and the negative electrode are distributed in parallel.

Further, the positive electrode, electrolyte and negative electrode of the battery are arranged in order from left to right, the left insulating non-thermal insulating layer is arranged on the left side of the positive electrode of the battery, and the right insulating non-thermal insulating layer is arranged on the right side of the negative electrode of the battery.

Further, the right side of the left PN type conductive layer is connected to the left side of the left insulating non-thermal insulation layer, the left side of the left PN type conductive layer is connected to the right ends of the left P-type doped region and the left N-type doped region, and the left P The left ends of the left P-type doped region and the left N-type doped region are respectively connected to the right side of the left P-type conductive layer and the left N-type conductive layer; the right ends of the right P-type doped region and the right N-type doped region The left side of the PN-type conductive layer is connected, the left ends of the right P-type doped region and the right N-type doped region are respectively connected to the right side of the right P-type conductive layer and the right N-type conductive layer, and the right P-type conductive layer and the right N-type conductive layer are respectively connected. The left side of the type conducting layer is connected to the right side of the right insulating non-thermal insulating layer.

Further, the right N-type conductive layer leads to node A, the left P-type conductive layer leads to node B, and the positive electrode of the battery leads to a positive line, which can be selected from node A or node B through switch S1. The left N-type conductive layer leads out the node C, the right P-type conductive layer leads out the node D, and the negative electrode of the battery leads out the negative line, and the negative line can be connected to the node C or the node D through the switch S2 with selective on and off.

Further, the material of the left PN-type conductive layer, left P-type conductive layer, left N-type conductive layer, right PN-type conductive layer, right P-type conductive layer, and right N-type conductive layer is copper sheet, or iron sheet, or nickel sheet.

Further, the doped region in the left PN-type semiconductor or the right PN-type semiconductor is Bi2Te3-based alloy, PbX compound, X is S, Se, Te, silicon-based thermoelectric material, cage-like structure skutterudite or half-Heusler alloy.

Further, the insulating and non-heat-insulating layer material is polyimide film or ceramic plate. Its main features are: 1. Prevent the direct contact between the positive electrode or negative electrode of the battery and P, N-type semiconductor materials, 2. Achieve uniform transmission of heat flow density inside the structure, so as to maximize the thermoelectric performance of the material.

The beneficial effects of the present invention are as follows.

The invention designs a new integrated structure of an intelligent thermoelectric battery by means of direct contact, and integrates the thermoelectric material and the battery. This method can perform intelligent thermal control on the single cells inside the battery pack to achieve a more efficient thermal management technology and cut off the occurrence of thermal runaway from the root cause. In addition, the Seebeck voltage generated based on the temperature difference can directly store energy inside the battery during the charging process of the battery, and can improve the overall output voltage during the discharging process. The advantages of this intelligent integrated new structure solve the contradiction between the difficulty of achieving high energy density and high safety performance for traditional batteries at the same time, and the use of this new structure is expected to guide the development and application of a new generation of high-performance batteries.

### BRIEF DESCRIPTION OF THE DRAWINGS

FIG. 1 is the conceptual diagram of the overall scheme of the integrated structure of the intelligent thermoelectric battery provided by the present invention;

FIG. 2 is a schematic diagram of a thermoelectric conversion Seebeck effect-power generation module;

FIG. 3 is a schematic diagram of the electrothermal conversion Peltier effect-refrigeration module;

FIG. 4 is a composite structure design diagram of using the thermoelectric Seebeck effect to directly store electric energy into the battery during the charging process;

FIG. 5 is a design diagram of a composite structure for controlling thermal runaway by using the Peltier effect of electrothermal conversion during the charging process.

FIG. 6 is the design diagram of the composite structure using the thermoelectric Seebeck effect to increase the output voltage during the discharge process

FIG. 7 is a design diagram of a composite structure for controlling thermal runaway by using the peltier effect of electrothermal conversion during the discharge process.

Reference numbers in the Figs are as follows. 1. Left P-type conductive layer, 2. Left N-type conductive layer, 3. Left P-type doped region, 4. Left N-type doped region, 5. Left PN-type conductive layer, 6. Left insulating layer Insulation layer, 7. Positive electrode, 8. Electrolyte, 9. Diaphragm, 10. Negative electrode, 11. Right insulating non-insulating layer, 12. Right P-type conductive layer, 13. Right N-type conductive layer, 14. Right P-type doped layer Impurity region, 15. Right N-type doped region, 16. Right PN-type conductive layer.

### DETAILED DESCRIPTION OF THE PREFERRED EMBODIMENT

The present invention will be further described below with reference to the accompanying drawings.

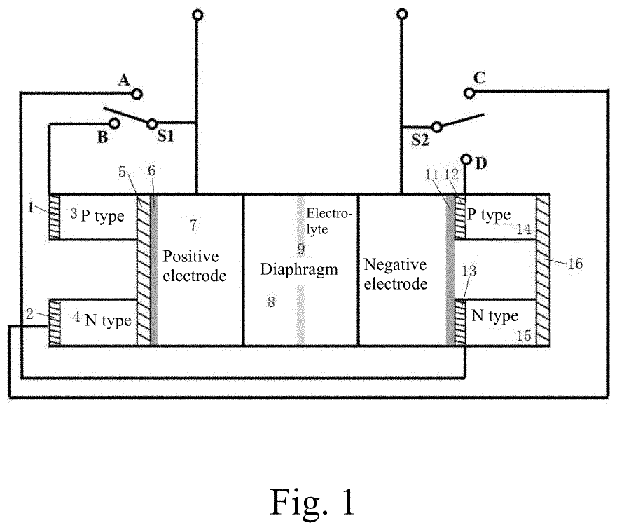

FIG. 1 is an overall scheme of an integrated structure of an intelligent thermoelectric battery provided by the present invention, the structure comprises: a left PN type semiconductor, a battery, and a right PN type semiconductor; the left PN type semiconductor The PN-type semiconductor is connected to the negative electrode of the battery through the right insulating non-heat-insulating layer; the left PN-type semiconductor comprises: a left PN-type conductive layer, a left P-type doped region, a left N-type doped region, a left P-type conductive layer, and a left N-type conductive layer. type conductive layer; one end of the left P-type doped region and the left N-type doped region is connected to the left PN-type conductive layer, and the rest are kept electrically isolated; the other end of the left P-type doped region is connected to the left P-type conductive layer, The other end of the left N-type doped region is connected to the left N-type conductive layer; the left PN-type conductive layer is connected to the positive electrode of the battery through the left insulating non-thermal insulation layer; the right PN-type semiconductor comprises: a right PN-type conductive layer, a right P-type doped region, right N-type doped region, right P-type conductive layer, right N-type conductive layer; one end of the right P-type doped region and right N-type doped region is connected to the right PN-type conductive layer, and the rest Maintain electrical isolation; the other end of the right P-type doped region is connected to the right P-type conductive layer, and the other end of the right N-type doped region is connected to the right N-type conductive layer; the right P-type conductive layer and the right N-type conductive layer are connected The layer is connected to the negative electrode of the battery through the right insulating non-insulating layer.

The conductive layer is a copper sheet, an iron sheet or a nickel sheet, and its thickness is 0.4-0.8 mm. The thermoelectric materials are, but are not limited to, Bi2Te3-based alloys, PbX (X═S, Se, Te) compounds, silicon-based thermoelectric materials, cage-like skutterudite, semi-Heusler alloys, and the like. The specific N-type or P-type semiconductor material can be obtained by doping or ion implanting the above-mentioned materials.

The insulating non-thermal insulating layer material is specifically an insulating material (polyimide film or ceramic flat plate), and its thickness is 0.025-0.225 nanometers. Its main features are: 1. Prevent the direct contact between the positive electrode or negative electrode of the battery and P, N-type semiconductor materials, 2. Achieve uniform transmission of heat flow density inside the structure, so as to maximize the thermoelectric performance of the material. The positive electrode material of the battery is a positive electrode material commonly used in lithium ion batteries, such as lithium cobalt oxide, lithium manganate, lithium iron phosphate, and the like. The electrolyte is commonly used electrolytes for lithium-ion batteries, such as lithium perchlorate, lithium hexafluorophosphate, and the like. The negative electrode material of the battery is the negative electrode material commonly used in lithium ion batteries, such as graphite, lithium titanate, silicon-based negative electrode, metal lithium, and the like. The thermoelectric P, N-type semiconductor materials may not be limited to a pair of P, N-type materials, and can be customized according to actual batteries, so as to achieve better working effects. S1 and S2 are temperature control switches, wherein S1 controls the connection and disconnection of A and B, and S2 controls the connection and disconnection of C and D.

The working principle of the new integrated structure of the intelligent thermoelectric battery according to the present invention is as follows:

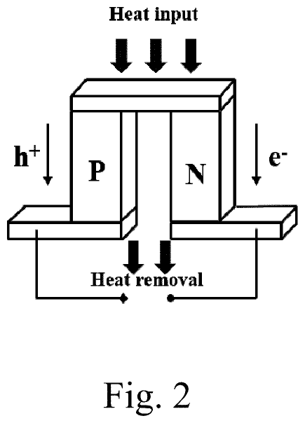

FIG. 2 is a schematic diagram of a thermoelectric conversion Seebeck effect-power generation module. When there is a temperature difference, the carriers in the conductor will move from the hot end to the cold end under the temperature gradient, and accumulate at the cold end, connecting through the conductive layer, and the Seebeck voltage will be generated.

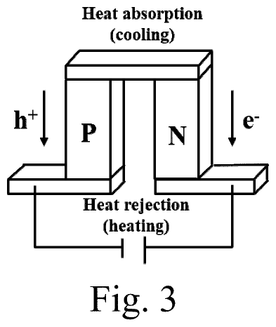

FIG. 3 is a schematic diagram of the electrothermal conversion Peltier effect-refrigeration module. When a current passes through, the electrons move in a directional motion and are connected through the conductive layer, and the carriers in the conductor carry heat from one end to the other to achieve cooling.

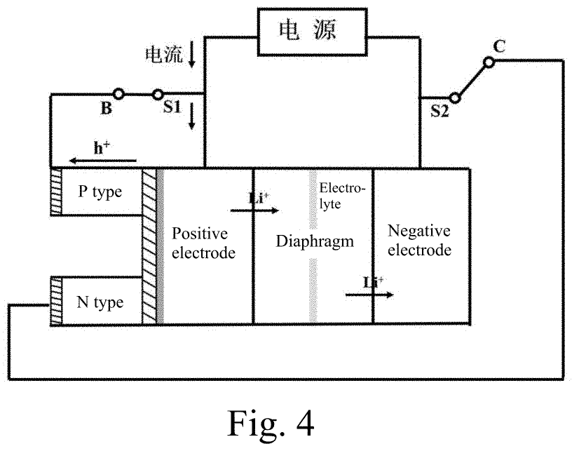

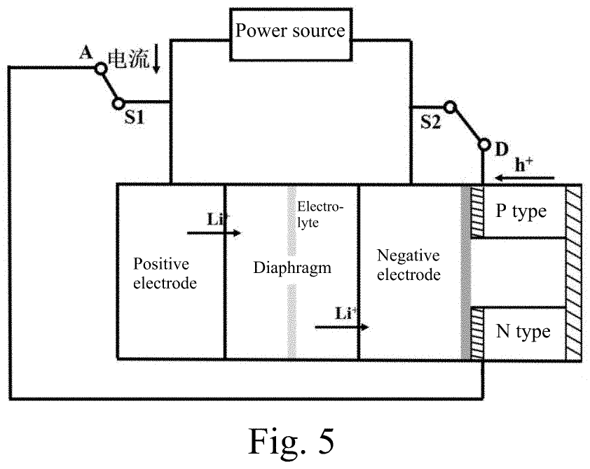

FIG. 4 shows the working principle diagram of the integrated structure of an intelligent thermoelectric battery that uses the Seebeck effect of thermoelectric conversion to directly store energy in the battery during the charging process. When the battery is charged, the electrons on the positive electrode will move to the negative electrode through the external circuit, and the positive lithium ions Li+ will pass through the electrolyte and the separator from the positive electrode, and finally reach the negative electrode, where they stay and combine with the electrons and are reduced to Li mosaic in the carbon material of the negative electrode. During this process, the internal temperature of the battery increases due to the heat generated by the chemical reaction inside the battery. When the size of the temperature T (the temperature is set to 80-100° C. according to the actual application) will not cause thermal runaway of the battery, the temperature control switch S1 is connected to B, and S2 is connected to C. Because the direct contact method is used to embed P and N type semiconductor materials in this structure. At this time, due to the temperature difference (that is, the temperature difference between the temperature formed inside the battery and the ambient temperature), an additional Seebeck voltage will be generated, and this part of the voltage can be directly stored inside the battery. When the size of the temperature T will cause the battery to run out of control, the temperature control switch S1 is connected to A, and S2 is connected to D. As shown in FIG. 5, the electrothermal conversion Peltier effect is used to achieve refrigeration. When the current generated by the power source flows through the loop, the electrons move directionally and connect to the P and N-type semiconductor materials through the conductive layer, and the carriers in the conductor will carry the heat (the heat generated by the battery heating) from one end to the other end for cooling.

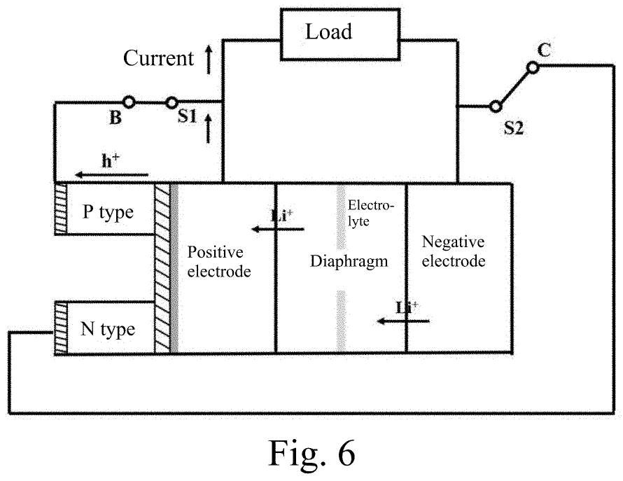

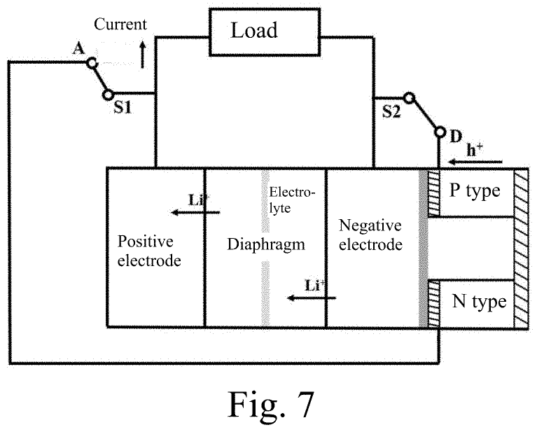

FIG. 6 shows the working principle diagram of the integrated structure of an intelligent thermoelectric battery that utilizes the Seebeck effect of thermoelectric conversion to increase the output voltage during the discharge process of the battery. When the battery is discharged, the Li embedded in the carbon material of the negative electrode will lose electrons, the electrons on the negative electrode will move to the positive electrode through the external circuit, and the positive lithium ion Li+ will cross the electrolyte and the separator material from the negative electrode to reach the positive electrode, and will interact with the positive electrode material. electrons are combined together. During this process, the internal temperature of the battery increases due to the heat generated by the chemical reaction inside the battery. When the size of the temperature T will not cause thermal runaway of the battery, the temperature control switch S1 is connected to B, and S2 is connected to C. When there is a temperature difference (that is, the temperature difference between the temperature developed inside the battery and the ambient temperature), the Seebeck voltage is generated, which together with the voltage provided by the battery powers the load. The output voltage provided by a normal battery during operation is U1, and the Seebeck voltage generated by the thermoelectric Seebeck effect is U2, so the total output voltage of the entire system is the sum of the two parts (U=U1+U2), and the final total output voltage is obtained. promote. When the size of the temperature T will cause the thermal runaway of the battery, the temperature control switch S1 is connected to A, and S2 is connected to D. As shown in FIG. 7, the electrothermal conversion Peltier effect is used to achieve refrigeration. When the current generated by the battery passes through the loop, the electrons move directionally and connect to the PN-type semiconductor material through the conductive layer, and the carriers in the conductor will carry the heat (the heat generated by the heating of the battery) from one end to the other, to achieve refrigeration.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An intelligent thermoelectric-battery integrated structure comprising: a left PN type semiconductor, a battery, and a right PN type semiconductor; wherein the left PN type semiconductor is connected to the positive electrode of the battery through a left insulating non-thermal insulation layer, and the right PN type semiconductor is connected to the negative electrode of the battery through the right insulating non-thermal insulating layer; wherein:
the left PN-type semiconductor comprises: a left PN-type conductive layer, a left P-type doping region, a left N-type doping region, a left P-type conductive layer, a left N-type conductive layer; a left P-type doping region and a left N-type doping region One end of the doped region is connected to the left PN-type conductive layer, and the rest is kept electrically isolated; the other end of the left P-type doped region is connected to the left P-type conductive layer, and the other end of the left N-type doped region is connected to the left N-type conductive layer Layer connection; the left PN type conductive layer is connected to the positive electrode of the battery through the left insulating non-thermal insulation layer;
the right PN-type semiconductor comprises: a right PN-type conductive layer, a right P-type doped region, a right N-type doped region, a right P-type conductive layer, a right N-type conductive layer; a right P-type doped region and a right N-type doped region One end of the doped region is connected to the right PN-type conductive layer, and the rest is kept electrically isolated; the other end of the right P-type doped region is connected to the right P-type conductive layer, and the other end of the right N-type doped region is connected to the right N-type conductive layer connection; the right P-type conductive layer and the right N-type conductive layer are connected to the negative electrode of the battery through the right insulating non-thermal insulating layer.

2. The intelligent thermoelectric-battery integrated structure, as recited in claim 1, wherein the battery comprises a positive electrode, an electrolyte, and a negative electrode; the electrolyte is provided with a diaphragm; the positive electrode, the electrolyte, and the negative electrode are arranged in order from left to right; the insulating and non-thermal insulating layer is arranged on the right side of the negative electrode of the battery

3. The intelligent thermoelectric-battery integrated structure, as recited in claim 1, wherein the material of the left PN-type conductive layer, left P-type conductive layer, left N-type conductive layer, right PN-type conductive layer, right P-type conductive layer, and right N-type conductive layer is copper sheet, iron sheet, or nickel sheet.

4. The intelligent thermoelectric-battery integrated structure, as recited in claim 1, wherein the doped region in the left PN type semiconductor or the right PN type semiconductor is Bi2Te3 based alloy, PbX compound, X is S, Se, Te, silicon based thermoelectric material, cage structure skutterudite or half Heusler alloy.

5. The intelligent thermoelectric-battery integrated structure, as recited in claim 1, wherein the insulating and non-heat-insulating layer material is polyimide film or ceramic plate.

6. The intelligent thermoelectric-battery integrated structure, as recited in claim 1, wherein the right side of the left PN type conductive layer is connected to the left side of the left insulating non-thermal insulation layer, the left side of the left PN type conductive layer is connected to the right ends of the left P-type doped region and the left N-type doped region, and the left P the left ends of the left P-type doped region and the left N-type doped region are respectively connected to the right side of the left P-type conductive layer and the left N-type conductive layer; the right ends of the right P-type doped region and the right N-type doped region The left side of the PN-type conductive layer is connected, the left ends of the right P-type doped region and the right N-type doped region are respectively connected to the right side of the right P-type conductive layer and the right N-type conductive layer, and the right P-type conductive layer and the right N-type conductive layer are respectively connected; the left side of the type conducting layer is connected to the right side of the right insulating non-thermal insulating layer.

7. The intelligent thermoelectric-battery integrated structure, as recited in claim 1, wherein the right N-type conductive layer leads to node A, the left P-type conductive layer leads to node B, and the positive electrode of the battery leads to a positive line, which can be selectively connected to node A or node B through switch S1; the left N-type conductive layer leads out node C, the right P-type conductive layer leads out node D, and the negative electrode of the battery leads out a negative line, which can be selectively connected to node C or node D through switch S2.
